(19) United States
(12) Patent Application Publication
(10) Pub. No.: US 2026/0205096 A1
(43) Pub. Date: Jul. 16, 2026

(54) ADAPTIVE FILTER AND ASSOCIATED CONTROL METHOD

(71) Applicant: Faraday Technology Corp., Hsin-Chu City (TW)

(72) Inventors: Po-Hsuan Lee, Hsin-Chu City (TW); Sheng-Yu Huang, Hsin-Chu City (TW); Yu-Hsiang Tsai, Hsin-Chu City (TW); Shih-Yi Shih, Hsin-Chu City (TW)

(73) Assignee: Faraday Technology Corp., Hsin-Chu City (TW)

(21) Appl. No.: 19/080,926

(22) Filed: Mar. 16, 2025

(30) Foreign Application Priority Data
Jan. 10, 2025 (TW) 114100992

(51) Int. Cl. H03H 21/00

(52) U.S. Cl. CPC H03H 21/0043; H03H 2021/0049

(57) ABSTRACT

The present invention provides an adaptive filter, wherein a filtering unit of the adaptive filter includes a first calculation circuit, a second calculation circuit, a third calculation circuit and an adder. The first calculation circuit is configured to generate a first part according to the input signal. The second calculation circuit is configured to generate a second part according to the input signal. The third calculation circuit establishes multiple items in a storage element, each item corresponding to two adjacent coefficients of the multiple coefficients, and each item records a product of the two adjacent coefficients; and divides the multiple items into multiple groups, with each group including at least one item, and sequentially and non-simultaneously updates the multiple groups of items to generate a third part. The adder is configured to sum the first part, the second part, and the third part to generate a filtered signal.

### BACKGROUND OF THE INVENTION

### 1. Field of the Invention

The present invention relates to an adaptive filter.

### 2. Description of the Prior Art

In the design of digital filters, adders, multipliers, and delay elements are typically included. Due to the relatively high complexity of multipliers in circuit design, if a digital filter is designed with a higher order to achieve better filtering performance, the manufacturing cost of the digital filter will increase. In a general digital filter, the relationship between an input signal and a filtered signal can be expressed by the following formula:

$$z ( n ) = {\sum }_{k = 0}^{N - 1} x ( n - k ) {C}_{k} ( n ) ; \qquad ( 1 )$$

where x(n) is the input signal, z(n) is the filtered signal, N is an order of the filter, Ck represents the k-th coefficient, and Cₖ(n) represents the coefficient corresponding to the input signal x(n) after k delays at time “n”. Therefore, in the above digital filter circuit design, N multipliers are required.

To address the issue of excessive multipliers in traditional digital filters, U.S. Patent Publication No. US2002/0027953 A1 discloses a decomposition technique that can decompose the formula (1) into three parts. This technique employs estimation and recursive computation methods to reduce the number of multipliers in the filter. However, although this technique can reduce the number of multipliers, it introduces estimation errors, which can affect the filtering quality.

### SUMMARY OF THE INVENTION

Therefore, one of the objectives of the present invention is to propose a filter that can maintain good filtering quality with fewer multipliers, in order to solve the problems described in the prior art.

According to one embodiment of the present invention, an adaptive filter comprising an updating unit and a filtering unit is disclosed. The updating unit is configured to update multiple coefficients of the adaptive filter. The filtering unit is configured to process an input signal with the multiple coefficients to generate a filtered signal. The filtering unit comprises a first calculation circuit, a second calculation circuit, a third calculation circuit and an adder. The first calculation circuit is configured to generate a first part according to the input signal. The second calculation circuit is configured to generate a second part according to the input signal. The third calculation circuit is configured to generate a third part, wherein the third calculation circuit establishes multiple items in a storage element, each item corresponding to two adjacent coefficients of the multiple coefficients, and each item records a product of the two adjacent coefficients; and the third calculation circuit divides the multiple items into multiple groups, with each group including at least one item, and sequentially and non-simultaneously updates the multiple groups of items to generate the third part. The adder is configured to sum the first part, the second part, and the third part to generate the filtered signal.

According to one embodiment of the present invention, a control method of an adaptive filter comprises the steps of: updating multiple coefficients of the adaptive filter; generating a first part according to an input signal of the adaptive filter; generating a second part according to the input signal; establishing multiple items in a storage element, wherein each item corresponds to two adjacent coefficients, and each item records a product of the two adjacent coefficients; and dividing the multiple items into multiple groups, wherein each group comprises at least one item; and sequentially and non-simultaneously updating the multiple groups of items to generate a third part; and summing the first part, the second part, and the third part to generate a filtered signal of the adaptive filter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a system according to an embodiment of the present invention.

FIG. 2 is a schematic diagram of a filtering unit according to an embodiment of the present invention.

FIG. 3 is a schematic diagram of a third calculation circuit according to an embodiment of the present invention.

FIG. 4 is a flowchart of the operation of the third calculation circuit according to an embodiment of the present invention.

### DETAILED DESCRIPTION

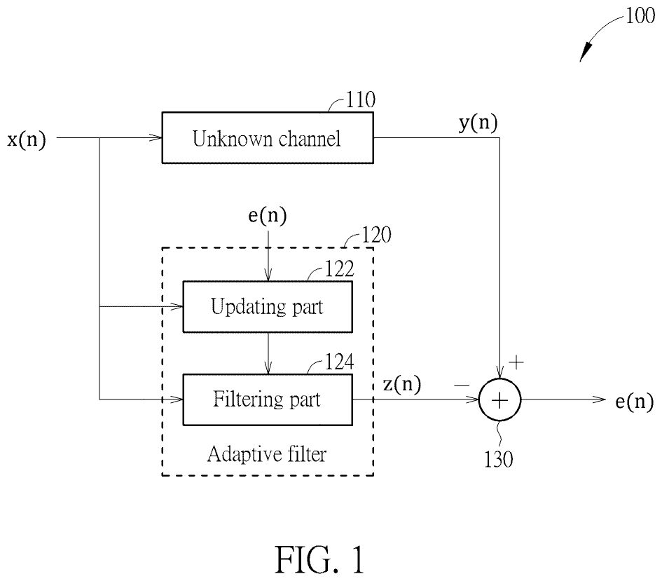

FIG. 1 is a schematic diagram of a system 100 according to an embodiment of the present invention. As shown in FIG. 1, the system 100 includes an unknown channel 110, an adaptive filter 120 and an adder 130, where the adaptive filter 120 includes an updating unit 122 and a filtering unit 124. In this embodiment, the adaptive filter 120 is a digital filter.

In the operation of the system 100, the unknown channel 110 receives an input signal x(n) to generate an output signal y (n), where the input signal x(n) can be a training signal, and the symbol “n” is used to represent time. The adaptive filter 120 is used to filter the input signal x(n) to generate a filtered signal z(n), where the filtered signal z(n) and the input signal x(n) can refer to the formula (1) mentioned in the prior art. The adder 130 then subtracts the filtered signal z(n) from the filtered signal y (n) to generate an error signal e (n). Furthermore, in the adaptive filter 120, the updating unit 122 is used to update N coefficients of the adaptive filter 120 based on the input signal x(n) and the error signal e (n), for example, using a least mean square (LMS) algorithm to update the coefficients. The filtering unit 124 is used to perform a convolution operation, as shown in formula (1), on the input signal x(n) and the N coefficients to generate the filtered signal z(n).

Since the focus of the present invention is on the design of the filtering unit 124, and the operation of the other components in system 100 is well-known to those skilled in the art, the following description will only focus on the filtering unit 124.

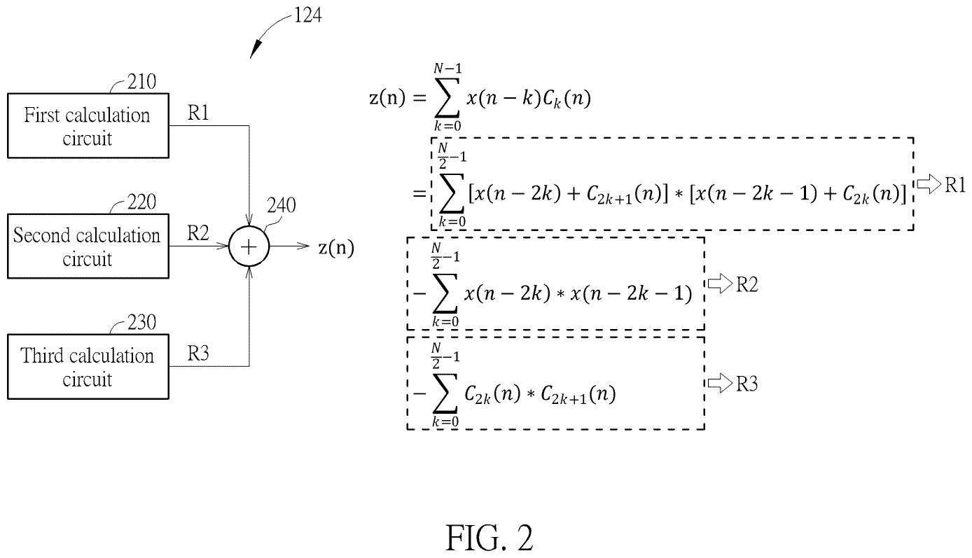

FIG. 2 is a schematic diagram of the filtering unit 124 according to an embodiment of the present invention. As shown in FIG. 2, the filtering unit 124 includes a first calculation circuit 210, a second calculation circuit 230, a third calculation circuit 230 and an adder 240. In this embodiment, the formula (1) mentioned above can be decomposed into three parts, R1, R2 and R3. That is, the filtered signal z(n) can be expressed as follows:

$$z ( n ) = {\sum }_{k = 0}^{N - 1} x ( n - k ) {C}_{k} ( n ) = R 1 + R 2 + R 3 ; \qquad ( 2 )$$

$$R 1 = {\sum }_{k = 0}^{\frac{N}{2} - 1} [ x ( n - 2 k ) + {C}_{2 k + 1} ( n ) ] * [ x ( n - 2 k - 1 ) + {C}_{2 k} ( n ) ] ; \qquad ( 3 )$$

$$R 2 = - {\sum }_{k = 0}^{\frac{N}{2} - 1} x ( n - 2 k ) * x ( n - 2 k - 1 ) ; \qquad ( 4 )$$

$$R 3 = - {\sum }_{k = 0}^{\frac{N}{2} - 1} {C}_{2 k} ( n ) * {C}_{2 k + 1} ( n ) ; \qquad ( 5 )$$

The first calculation circuit 210 is used to generate the first part R1, the second calculation circuit 220 is used to generate the second part R2, the third calculation circuit 230 is used to generate the third part R3, and the adder 240 is used to sum R1, R2 and R3 to obtain the filtered signal z(n).

In the above formulas (2) to (5), the first calculation circuit 210 requires (N/2) multipliers to generate the first part R1. The second calculation circuit 220 can use only two multipliers and employ a recursive operation to generate the second part R2. The third calculation circuit 230 can use only a few multipliers, such as one or two multipliers, to generate the third part R3. Therefore, compared to the adaptive filter in the prior art that uses N multipliers, this embodiment can reduce the manufacturing cost of the adaptive filter 120. Furthermore, since the first calculation circuit 210, the second calculation circuit 230 and the third calculation circuit 230 can accurately generate the first part R1, the second part R2 and the third part R3, respectively, this embodiment can avoid the estimation errors that might affect filtering quality, as seen in U.S. Patent Publication No. US2002/0027953 A1.

It should be noted that since the circuit designs of the first calculation circuit 210 and the second calculation circuit 220 can refer to U.S. Patent Application US 2002/0027953 A1, the following embodiment will focus on the description of the third calculation circuit 230.

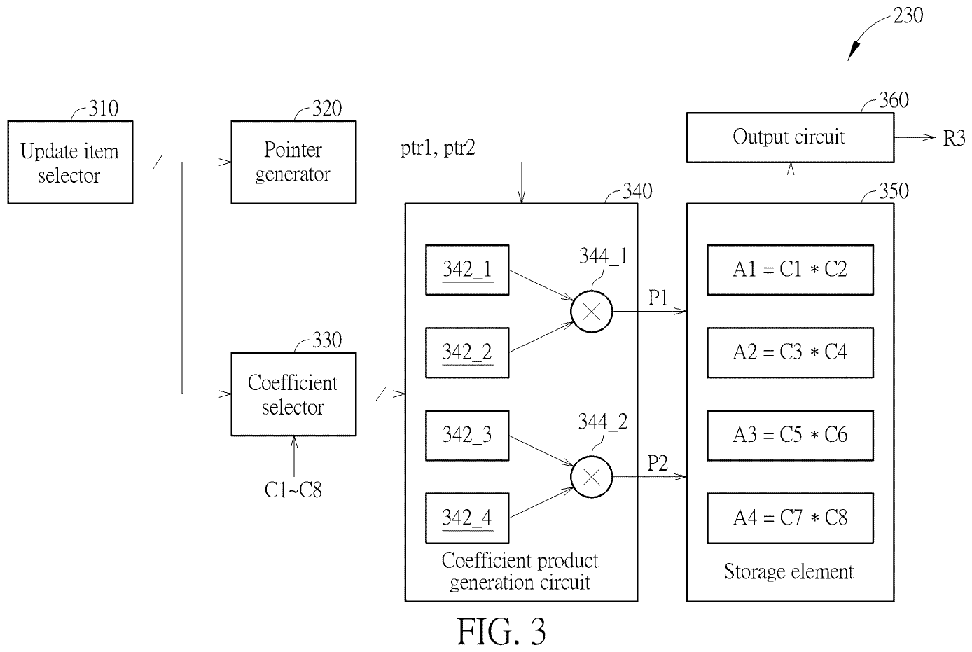

FIG. 3 is a schematic diagram of the third calculation circuit 230 according to an embodiment of the present invention. As shown in FIG. 3, the third calculation circuit 230 includes an update item selector 310, a pointer generator 320, a coefficient selector 330, a coefficient product generation circuit 340, a storage element 350 and an output circuit 360. In this embodiment, it is assumed that the adaptive filter 120 has eight coefficients C1-C8, and the storage element 350 stores four items A1-A4, where item A1 represents the product of the current coefficients C1 and C2, item A2 represents the product of the current coefficients C3 and C4, item A3 represents the product of the current coefficients C5 and C6, and item A4 represents the product of the current coefficients C7 and C8. Furthermore, the coefficient product generation circuit 340 includes multiple registers and at least one multiplier. In this embodiment, it is illustrated using four registers 342_1-342_4 and two multipliers 344_1 and 344_2.

In the operation of the third calculation circuit 230, the items C1-C8 in the storage element 350 are divided into multiple groups of items, with each group containing one or more items. The update item selector 310 selects a group of items in the storage element 350 that need to be updated. In the embodiment shown in FIG. 3, the storage element 350 includes two groups of items: the first group includes items A1 and A3, while the second group includes items A2 and A4. In this embodiment, during each cycle, the update item selector 310 selects one group of items that need to be updated. The duration of one cycle can be the time it takes for the input signal x(n) to undergo one delay, as mentioned in formula (1). In the first cycle, the update item selector 310 selects the first group of items A1 and A3.

Next, the pointer generator 320 generates two pointers ptr1 and ptr2 according to the items A1 and A3 selected by the update item selector 310, wherein the two pointers ptr1 and ptr2 point to physical addresses of the storage element 350 where items A1 and A3 are stored. Additionally, the coefficient selector 330 selects multiple coefficients C1, C2, C5 and C6 used to generate contents of items A1 and A3 selected by the update item selector 310. Then, the coefficients C1, C2, C5 and C6 are transmitted to the registers 342_1-342_4.

The multiplier 344_1 of the coefficient product generation circuit 340 multiplies the coefficients C1 and C2 stored in registers 342_1 and 342_2 to generate a product P1. The multiplier 344_2 of the coefficient product generation circuit 340 multiplies the coefficients C5 and C6 stored in registers 342_3 and 342_4 to generate a product P2. Then, the coefficient product generation circuit 340 writes the products P1 and P2 to the physical addresses in the storage element 350 pointed to by the pointers ptr1 and ptr2, respectively, to update the contents of items A1 and A3.

After the items A1 and A3 in the storage element 350 have been updated, the output circuit 360 sums all the items A1-A4 in the storage element 350 and adds a negative sign to the result, which is then used as the third part R3 generated by the third calculation circuit 230. Furthermore, after the third part R3 is generated by the third calculation circuit 230, the filtering unit 124 can generate/update the filtered signal z(n) according to the first part R1, second part R2 and third part R3 generated by the first calculation circuit 210, second calculation circuit 220 and third calculation circuit 230, respectively.

Then, in a second cycle immediately following the first cycle, the update item selector 310 selects the second group of items A2 and A4. Next, the pointer generator 320 generates two pointers ptr1 and ptr2 according to the items A2 and A4 selected by the update item selector 310, wherein the two pointers ptr1 and ptr2 point to physical addresses of the storage element 350 where items A2 and A4 are stored. Additionally, the coefficient selector 330 selects multiple coefficients C3, C4, C7 and C8 used to generate contents of items A2 and A4 selected by the update item selector 310. Then, the coefficients C3, C4, C7 and C8 are transmitted to the registers 342_1-342_4.

The multiplier 344_1 of the coefficient product generation circuit 340 multiplies the coefficients C3 and C4 stored in registers 342_1 and 342_2 to generate a product P1. The multiplier 344_2 of the coefficient product generation circuit 340 multiplies the coefficients C7 and C8 stored in registers 342_3 and 342_4 to generate a product P2. Then, the coefficient product generation circuit 340 writes the products P1 and P2 to the physical addresses in the storage element 350 pointed to by the pointers ptr1 and ptr2, respectively, to update the contents of items A2 and A4.

After the items A2 and A4 in the storage element 350 have been updated, the output circuit 360 sums all the items A1-A4 in the storage element 350 and adds a negative sign to the result, which is then used as the third part R3 generated by the third calculation circuit 230. It should be noted that, at this point, only the items A2 and A4 are updated during the second cycle when calculating the third part R3, meaning that the values of items A1 and A3 were generated in the first cycle. Furthermore, after the third part R3 is generated by the third calculation circuit 230, the filtering unit 124 can generate/update the filtered signal z(n) according to the first part R1, second part R2 and third part R3 generated by the first calculation circuit 210, second calculation circuit 220 and third calculation circuit 230, respectively.

Similarly, in the subsequent third cycle, similar to the operation in the first cycle, the update item selector 310 selects the first group of items A1 and A3, and updates the items A1 and A3 in the storage element for the third calculation circuit 230 to generate the third part R3. In the following fourth cycle, similar to the operation in the second cycle, the update item selector 310 selects the second group of items A2 and A4, and updates the items A2 and A4 in the storage element for the third calculation circuit 230 to generate the third part R3.

In the above embodiment, the updating unit 122 of the adaptive filter 120 updates a portion of the coefficients C1-C8 during each cycle. For example, in the first cycle, coefficients C1 and C5 are updated; in the second cycle, coefficients C3 and C7 are updated; in the third cycle, coefficients C2 and C6 are updated; and in the fourth cycle, coefficients C4 and C8 are updated, and so on. However, the coefficient updates described above are merely provided as examples and are not intended to limit the present invention. In other embodiments, the number of coefficients updated in each cycle and the specific coefficients updated can be designed differently based on the designer's considerations.

As described in the above embodiment, by grouping the items A1-A4 in the storage element 350 and sequentially and non-simultaneously updating each group of items, the third calculation circuit 230 can accurately generate the third part R3 of formula (5) with only a few multipliers. This approach allows the filtering quality to be maintained while saving on manufacturing costs. In this embodiment, the number of multipliers in the third calculation circuit 230 is determined by the number of items in each group. For example, in the embodiment shown in FIG. 3, each group includes two items, so the coefficient product generation circuit 340 includes two multipliers. If each group includes only one item, the coefficient product generation circuit 340 will only require one multiplier. However, in this case of each group including only one item, it would take four cycles to complete one update of the items A1-A4 in the storage element 350.

It should be noted that the architecture shown in FIG. 3 is merely an example for illustration and is not intended to limit the present invention. In other embodiments, the adaptive filter 120 may have N coefficients, the storage element 350 may include multiple items, with the number of items being (N/2). Each item corresponds to two adjacent coefficients, with each pair of adjacent coefficients being distinct, and each item representing the product of the two adjacent coefficients. Additionally, the third calculation circuit 230 divides the multiple items into multiple groups, where each group includes M items, and the third calculation circuit 230 sequentially updates each group of items to generate the third part R3, with different groups of items being updated in different cycles. The value of N can be any suitable positive integer, and M can be any suitable positive integer less than N. In particular, when M is less than ((N/2)−2), this can offer the advantage of reducing the number of multipliers compared to prior art, with more significant effects when M is much smaller than ((N/2)−2).

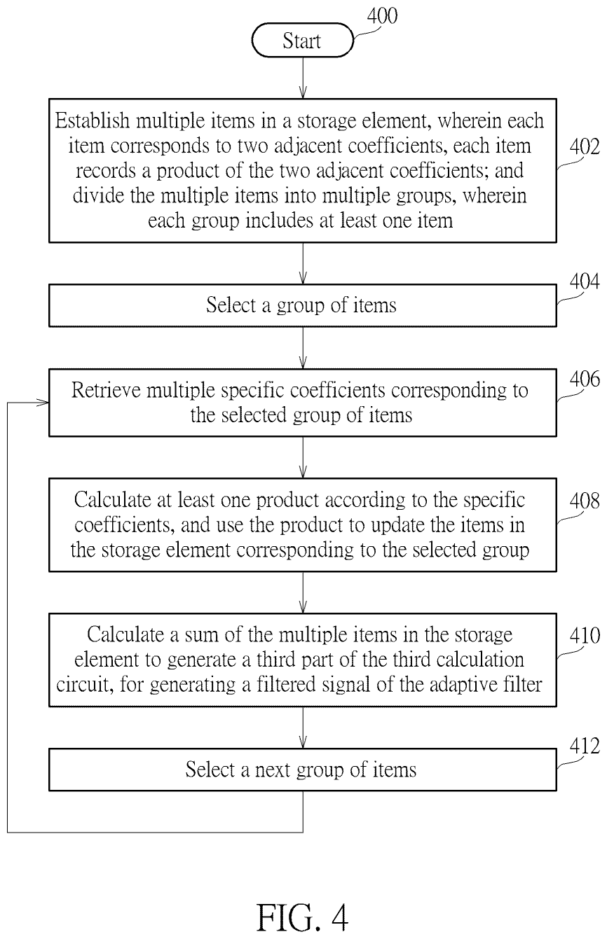

FIG. 4 is a flowchart illustrating the operation of the third calculation circuit 230 according to an embodiment of the present invention. Referring to the content described in the above embodiments, the flow is described as follows: Step 400: the flow starts.

Step 402: establish multiple items in a storage element, wherein each item corresponds to two adjacent coefficients, each item records a product of the two adjacent coefficients; and divide the multiple items into multiple groups, wherein each group includes at least one item.

Step 404: select a group of items.

Step 406: retrieve multiple specific coefficients corresponding to the selected group of items.

Step 408: calculate at least one product according to the specific coefficients, and use the product to update the items in the storage element corresponding to the selected group.

Step 410: calculate a sum of the multiple items in the storage element to generate a third part of the third calculation circuit, for generating a filtered signal of the adaptive filter.

Step 412: select a next group of items, and the flow goes back to Step 406.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An adaptive filter, comprising:
an updating unit, configured to update multiple coefficients of the adaptive filter;
a filtering unit, configured to process an input signal with the multiple coefficients to generate a filtered signal;
wherein the filtering unit comprises:
a first calculation circuit, configured to generate a first part according to the input signal;
a second calculation circuit, configured to generate a second part according to the input signal;
a third calculation circuit, configured to generate a third part, wherein the third calculation circuit establishes multiple items in a storage element, each item corresponding to two adjacent coefficients of the multiple coefficients, and each item records a product of the two adjacent coefficients; and the third calculation circuit divides the multiple items into multiple groups, with each group including at least one item, and sequentially and non-simultaneously updates the multiple groups of items to generate the third part; and
an adder, configured to sum the first part, the second part, and the third part to generate the filtered signal.

2. The adaptive filter of claim 1, wherein the first part is
$$R 1 = {\sum }_{k = 0}^{\frac{N}{2} - 1} [ x ( n - 2 k ) + {C}_{2 k + 1} ( n ) ] * [ x ( n - 2 k - 1 ) + {C}_{2 k} ( n ) ] ,$$
the second part is
$$R 2 = - {\sum }_{k = 0}^{\frac{N}{2} - 1} x ( n - 2 k ) * x ( n - 2 k - 1 ) ,$$
and the third part is
$$R 3 = - {\sum }_{k = 0}^{\frac{N}{2} - 1} {C}_{2 k} ( n ) * {C}_{2 k + 1} ( n ) ,$$
wherein x(n) is the input signal, N is a number of the multiple coefficients, Ck represents a k-th coefficient, and Ck (n) represents the coefficient corresponding to the input signal x(n) after k delays at time “n”.

3. The adaptive filter of claim 1, wherein in a first cycle, the third calculation circuit selects a first group of items, retrieves multiple first coefficients corresponding to the first group of items, calculates at least one first product according to the multiple first coefficients, uses the at least one first product to update the items in the storage element corresponding to the first group of items, and sums the multiple items in the storage element to generate the third part; and in a second cycle immediately following the first cycle, the third calculation circuit selects a second group of items, retrieves multiple second coefficients corresponding to the second group of items, calculates at least one second product according to the multiple second coefficients, uses the at least one second product to update the items in the storage element corresponding to the second group of items, and sums the multiple items in the storage element to generate the third part.

4. The adaptive filter of claim 1, wherein the third calculation circuit comprises:
an update item selector, configured to select a group of items;
a pointer generator, configured to generate at least one pointer according to the selected group of items;
a coefficient selector, configured to retrieve multiple specific coefficients corresponding to the selected group of items; and
a coefficient product generation circuit, configured to calculate at least one product according to the multiple specific coefficients, and use the at least one product to update the items in the storage element corresponding to the selected group of items;
wherein the third calculation circuit calculates a sum of the multiple items in the storage element to generate the third part.

5. The adaptive filter of claim 4, wherein the group of items comprises M items, where M is a positive integer, and the coefficient product generation circuit comprises only M multipliers to generate M products for updating the M items in the storage element.

6. The adaptive filter of claim 1, wherein a number of the multiple coefficients of the adaptive filter is N, a number of the multiple items recorded in the storage element is (N/2), each group of items comprises M items, N is a positive integer, and M is a positive integer less than N.

7. A control method of an adaptive filter, comprising:
updating multiple coefficients of the adaptive filter;
generating a first part according to an input signal of the adaptive filter;
generating a second part according to the input signal;
establishing multiple items in a storage element, wherein each item corresponds to two adjacent coefficients, and each item records a product of the two adjacent coefficients; and
dividing the multiple items into multiple groups, wherein each group comprises at least one item; and sequentially and non-simultaneously updating the multiple groups of items to generate a third part; and
summing the first part, the second part, and the third part to generate a filtered signal of the adaptive filter.

8. The control method of claim 7, wherein the first part is
$$R 1 = {\sum }_{k = 0}^{\frac{N}{2} - 1} [ x ( n - 2 k ) + {C}_{2 k + 1} ( n ) ] * [ x ( n - 2 k - 1 ) + {C}_{2 k} ( n ) ] ,$$
the second part is
$$R 2 = - {\sum }_{k = 0}^{\frac{N}{2} - 1} x ( n - 2 k ) * x ( n - 2 k - 1 ) ,$$
and the third party is
$$R 3 = - {\sum }_{k = 0}^{\frac{N}{2} - 1} {C}_{2 k} ( n ) * {C}_{2 k + 1} ( n ) ,$$
wherein x(n) is the input signal, N is a number of the multiple coefficients, Ck represents a k-th coefficient, and Cₖ(n) represents the coefficient corresponding to the input signal x(n) after k delays at time “n”.

9. The control method of claim 7, wherein the step of generating the third part comprises:
in a first cycle, selecting a first group of items, retrieving multiple first coefficients corresponding to the first group of items, calculating at least one first product according to the multiple first coefficients, using the at least one first product to update the items in the storage element corresponding to the first group of items, and summing the multiple items in the storage element to generate the third part; and
in a second cycle immediately following the first cycle, selecting a second group of items, retrieving multiple second coefficients corresponding to the second group of items, calculating at least one second product according to the multiple second coefficients, using the at least one second product to update the items in the storage element corresponding to the second group of items, and summming the multiple items in the storage element to generate the third part.

10. The control method of claim 7, wherein a number of the multiple coefficients of the adaptive filter is N, a number of the multiple items recorded in the storage element is (N/2), each group of items comprises M items, N is a positive integer, and M is a positive integer less than N.
